(19) United States
(12) Patent Application Publication
(10) Pub. No.: US 2025/0386642 A1
(43) Pub. Date: Dec. 18, 2025

(54) DISPLAY DEVICE AND ELECTRONIC DEVICE COMPRISING DISPLAY DEVICE

(71) Applicant: Samsung Display Co., LTD., Yongin-si (KR)

(72) Inventors: Seong Sik AHN, Yongin-si (KR); Sun Ho KANG, Yongin-si (KR); Kyeong Min PARK, Yongin-si (KR); Eun Ju LEE, Yongin-si (KR)

(21) Appl. No.: 18/986,409

(22) Filed: Dec. 18, 2024

(30) Foreign Application Priority Data
Jun. 17, 2024 (KR) 10-2024-0078317
Jul. 18, 2024 (KR) 10-2024-0095057

(51) Int. Cl. H10H 29/85; H10H 29/49

(52) U.S. Cl. CPC H10H 29/8506; H10H 29/49

(57) ABSTRACT

A display device and an electronic device comprising the display device are provided. The display device includes a base layer including an active area and a peripheral area, the peripheral area around at least a portion of the active area and including a crack dam area, a light emitting element on the base layer in the active area, a crack dam on the base layer in the crack dam area and including a crack dam insulating layer, and a crack sensing line in the crack dam area.

The present application claims priority to and the benefit of Korean Patent Application No. 10-2024-0078317, filed on Jun. 17, 2024, and Korean Patent Application No. 10-2024-0095057, filed on Jul. 18, 2024, with the Korean Intellectual Property Office, the entire disclosures of both of which are incorporated herein by reference.

### BACKGROUND

### 1. Field

Embodiments of the present disclosure relate to a display device and an electronic device comprising the display device.

### 2. Description of the Related Art

Recently, as interest in information displays has increased, research and development into display devices continues to be conducted.

In some display devices, when an external impact is applied to the display device, a crack may occur inside the display device. As a result, it is desirable to develop a display device that may reduce or mitigate the risk of cracks that may occur inside the display device.

The above information disclosed in this Background section is only for enhancement of understanding of the background of the disclosure and therefore it may contain information that does not constitute prior art.

### SUMMARY

Aspects of one or more embodiments of the present disclosure relate to a display device and an electronic device comprising the display device in which a risk of a crack inside the display device may be reduced.

Aspects of one or more embodiments of the present disclosure relate to a display device and an electronic device comprising the display device in which a crack at positions inside the display device may be (thoroughly) sensed.

Additional aspects will be set forth in part in the description which follows and, in part, will be apparent from the description, or may be learned by practice of the presented embodiments of the disclosure.

According to one or more embodiments of the present disclosure, a display device includes a base layer having an active area and a peripheral area, the peripheral area around at least a portion of the active area and having a crack dam area, a light emitting element arranged on the base layer in the active area, a crack dam arranged on the base layer in the crack dam area, and including a crack dam insulating layer, and a crack sensing line arranged in the crack dam area.

According to one or more embodiments, the crack sensing line may include a plurality of crack sensing lines spaced and/or apart (e.g., spaced apart or separated) from each other in a direction from the active area to an outer portion of the display device;

According to one or more embodiments, the display device may further include connection portions electrically connected to the light emitting element, and a chip-on-film electrically connected to the connection portions. The active area may include a first side and second sides that are sides other than the first side. The connection portions may be arranged on the first side and may not be arranged on the second sides. The crack sensing line may be arranged on the first side and the second sides.

According to one or more embodiments, the crack sensing line may be electrically connected to at least one of the connection portions.

According to one or more embodiments, the crack dam may be arranged on the first side and the second sides.

According to one or more embodiments, the crack sensing line may be integral with the crack dam and may be arranged on the crack dam insulating layer.

According to one or more embodiments, the display device may further include at least one conductive layer in the active area and at least one insulating layer in the active area, and the crack sensing line may include the same material as the at least one conductive layer. The crack dam insulating layer may include the same material as the at least one insulating layer.

According to one or more embodiments, the display device may further include a lower conductive layer arranged on the base layer in the active area, an active layer overlapping the lower conductive layer in the active area, a gate conductive layer overlapping the active layer in the active area, and a transistor electrode layer electrically connected to the active layer. The crack sensing line may include the same material as the gate conductive layer.

According to one or more embodiments, the display device may further include a lower conductive layer arranged on the base layer in the active area, an active layer overlapping the lower conductive layer in the active area, a gate conductive layer overlapping the active layer in the active area, and a transistor electrode layer electrically connected to the active layer. The crack sensing line may include the same material as the lower conductive layer.

According to one or more embodiments, the crack sensing line may include a first crack sensing line, a second crack sensing line, and a third crack sensing line spaced and/or apart (e.g., spaced apart or separated) from each other.

According to one or more embodiments, the crack sensing line may include a conductive line in the peripheral area. The conductive line may be bent at a plurality of positions to form the first crack sensing line, the second crack sensing line, and the third crack sensing line without being disconnected.

According to one or more embodiments, the peripheral area may include a first area and a second area. The crack sensing line may include a plurality of lines in the first area and may include a single line in the second area.

According to one or more embodiments, the single line in the second area may be continuously connected to one of the plurality of lines in the first area.

According to one or more embodiments of the disclosure, a display device may include a base layer having an active area and a peripheral area, the peripheral area around at least a portion of the active area and having a dam area, a crack dam arranged on the base layer in the peripheral area, and including a crack dam insulating layer, a dam structure arranged between the crack dam and the active area, arranged in the dam area, and including a dam insulating layer, and a crack sensing line arranged in the dam area.

According to one or more embodiments, the crack sensing line may be integral with the dam structure.

According to one or more embodiments, the crack sensing line may be arranged on the dam insulating layer.

According to one or more embodiments, the dam structure may include a first dam structure and a second dam structure spaced and/or apart (e.g., spaced apart or separated) from each other. The crack sensing line may be in the first dam structure and may not be in the second dam structure.

According to one or more embodiments, the dam structure may include a first dam structure and a second dam structure spaced and/or apart (e.g., spaced apart or separated) from each other. The crack sensing line may be in each of the first dam structure and the second dam structure.

According to one or more embodiments, the dam structure may include a first dam structure and a second dam structure spaced and/or apart (e.g., spaced apart or separated) from each other. The crack sensing line may be in the second dam structure and may not be in the first dam structure.

According to one or more embodiments of the present disclosure, a display device includes a base layer having an active area and the peripheral area, the peripheral area around at least a portion of the active area, a light emitting element arranged on the base layer in the active area, a connection portion on the base layer in the peripheral area, arranged on (at) a side of the peripheral area, and electrically connected to the light emitting element; a chip-on-film having at least a portion electrically connected to the connection portion, a crack dam arranged on the base layer in the peripheral area and including a crack dam insulating layer, and a crack sensing line arranged in the peripheral area and including a plurality of crack sensing lines.

According to one or more embodiments of the present disclosure, an electronic device may comprises: a processor configured to provide input image data; a display device configured to display an image based on the input image data, the display device including sub-pixel areas; and a power supply configured to supply power to the display device. The display device may comprise: a base layer having an active area and a peripheral area, the peripheral area around at least a portion of the active area and having a crack dam area; a light emitting element on the base layer in the active area; a crack dam on the base layer in the crack dam area, and including a crack dam insulating layer; and a crack sensing line in the crack dam area.

According to one or more embodiments of the present disclosure, a display device and an electronic device comprising the display device in which a risk of a crack inside the display device may be reduced may be provided.

According to one or more embodiments of the present disclosure, a display device and an electronic device comprising the display device in which a crack at positions inside the display device may be (thoroughly) sensed may be provided.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serves to explain principles of present disclosure. In the drawings:

FIG. 1 is a schematic plan view illustrating a display device according to one or more embodiments of the present disclosure;

FIGS. 2 and 3 are each a schematic plan view illustrating a display device according to one or more embodiments of the present disclosure;

FIG. 4 is a schematic block diagram illustrating a crack dam according to one or more embodiments of the present disclosure;

FIGS. 5-7 are each a schematic cross-sectional view taken along the line A-A′ of FIG. 1, according to one or more embodiments of the present disclosure;

FIG. 8 is a schematic plan view illustrating a planar structure of a crack sensing line according to one or more embodiments of the present disclosure;

FIG. 9 is a schematic plan view illustrating a display device according to one or more embodiments of the present disclosure;

FIG. 10 is a schematic block diagram illustrating a crack dam according to one or more embodiments of the present disclosure; and

FIGS. 11-13 are each a schematic cross-sectional view taken along the line B-B′ of FIG. 9, according to one or more embodiments of the present disclosure.

FIG. 14 is a schematic block diagram illustrating an electronic device including a display device in accordance with an embodiment.

FIG. 15 is a schematic diagram illustrating an example where the electronic device of FIG. 14 is implemented as a smartphone.

FIG. 16 is a schematic diagram illustrating an example where the electronic device of FIG. 14 is implemented as a tablet computer.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

It will be further understood that the terms “comprises,” “comprising,” “includes,” “including,” “have,” “having,” “contain,” and “containing,” when used in this specification, specify the presence of the stated features, integers, steps, operations, elements, and/or components, but do not preclude the presence or addition of one or more other features, integers, steps, operations, elements, components, and/or groups thereof.

It will be understood that when an element, such as an area, layer, film, region or portion, is referred to as being “on” or “connected to,” another element, it can be directly on or connected to the other element, or one or more intervening elements may be present. In contrast, when an element or layer is referred to as being “directly on,” “directly connected to” or “immediately adjacent to” another element or layer, there are no intervening elements or layers present. In addition, it will also be understood that when an element is referred to as being “between” two elements, it can be the only element between the two elements, or one or more intervening elements may also be present.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In addition, in the present specification, when a portion of a layer, a layer, an area, a plate, or the like is formed on another portion, a forming direction is not limited to an upper direction but includes forming the portion on a side surface or in a lower direction. When a portion of a layer, a layer, an area, a plate, or the like is formed “under” another portion, this includes not only a case where the portion is “directly beneath” another portion but also a case where there is further another portion between the portion and the other portion.

Unless otherwise noted, like reference numerals denote like elements throughout the attached drawings and the written description, and thus, duplicative descriptions thereof may not be provided. In the drawings, the relative sizes of elements, layers, and regions may be exaggerated for clarity.

As used herein, the terms “use,” “using,” and “used” may be considered synonymous with the terms “utilize,” “utilizing,” and “utilized,” respectively.

As used herein, the term “and/or” includes any and all combinations of one or more of the associated listed items. Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

The disclosure relates to a display device and an electronic device comprising the display device. Hereinafter, a display device and an electronic device comprising the display device according to one or more embodiments are described with reference to the accompanying drawings.

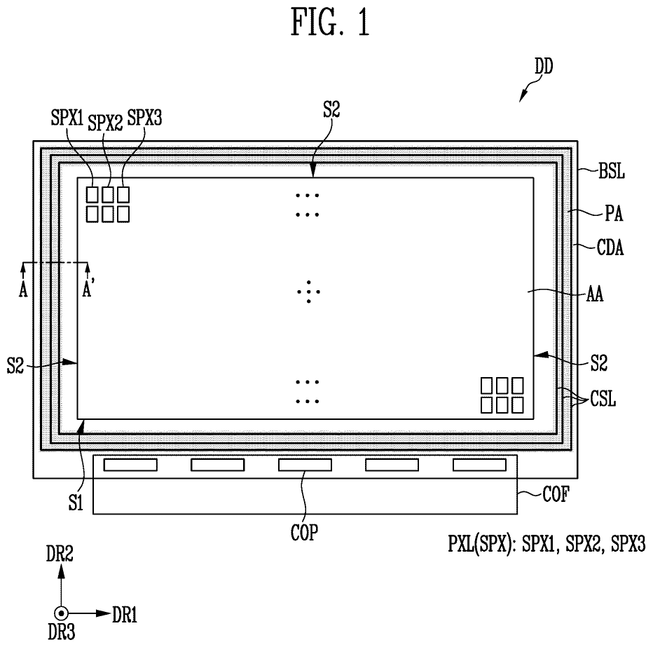

With reference to FIGS. 1 to 8, a display device DD according to one or more embodiments of the present disclosure is described.

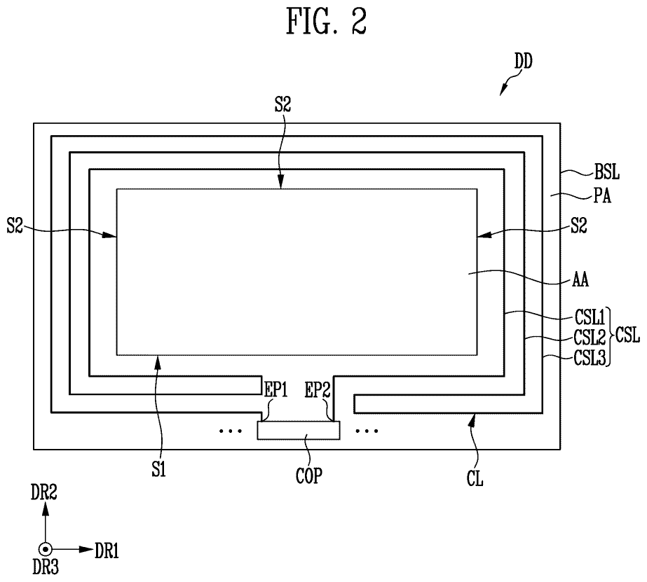

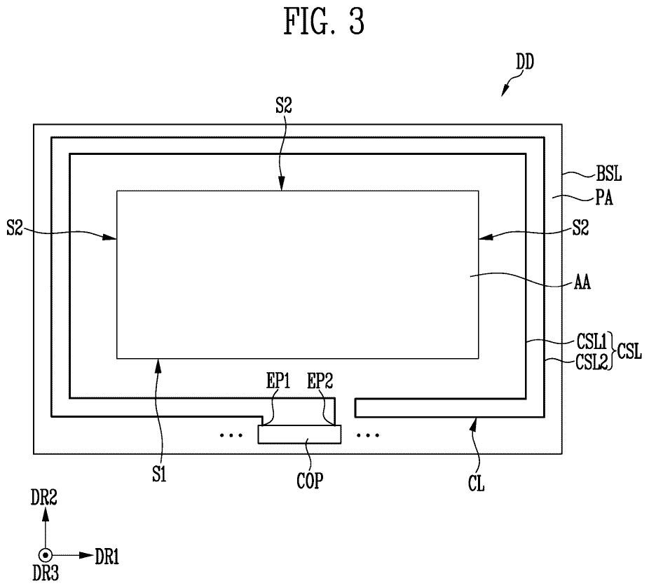

FIG. 1 is a schematic plan view illustrating a display device according to one or more embodiments of the present disclosure. FIGS. 2 and 3 are each a schematic plan view illustrating a display device according to one or more embodiments of the present disclosure. For convenience of description, other configurations other than a base layer BSL and a crack sensing line CSL are not provided in FIGS. 2 and 3.

Referring to FIGS. 1 to 3, the display device DD may include the base layer BSL and pixels PXL arranged on the base layer BSL. The display device DD may further include connection portions COP and a chip-on-film COF. The display device DD may further include a driving circuit part (for example, a gate driver, a data driver, a crack sensing circuit, and/or the like), a circuit board, and lines for driving the pixels PXL.

The display device DD (or the base layer BSL) may include an active area AA and a peripheral area PA. The peripheral area PA may refer to an area other than the active area AA. The peripheral area PA may be around (e.g., surround) at least a portion of the active area AA.

The base layer BSL may form a base surface of the display device DD. The base layer BSL may be formed across the active area AA and the peripheral area PA. According to one or more embodiments, the base layer BSL may be a lower substrate for disposing layers forming the display device DD. The base layer BSL may be a rigid or flexible substrate or film. For example, the base layer BSL may include a glass material. In one or more embodiments, the base layer BSL may include a silicon material. In one or more embodiments, the base layer BSL may include polyimide. However, the present disclosure is not limited thereto.

A plane (e.g., a plan view) defined in this specification may be defined based on a plane where the base layer BSL is arranged as a direction extending in a first direction DR1 and a second direction DR2. According to one or more embodiments, a third direction DR3 may be a thickness direction of the base layer BSL, and the third direction DR3 may be a light emission direction of the display device DD.

The active area AA may refer to an area where the pixels PXL are arranged. The peripheral area PA may mean an area in which the pixels PXL are not arranged. Lines connected to the pixels PXL of the active area AA and the connection portions COP may be arranged in the peripheral area PA.

According to one or more embodiments, the active area AA may include a first side S1 and second sides S2. The first side S1 may be one side of the active area AA where the connection portions COP are arranged. The second sides S2 may be other sides of the active area AA where the connection portions COP are not arranged. According to one or more embodiments, the first side S1 may be a lower side of the active area AA.

According to one or more embodiments, each of the pixels PXL (or sub-pixels SPX) may be arranged according to a stripe or PENTILE® arrangement structure (for example, an RGBG matrix, an RGBG structure, or RGBG matrix structure), but the present disclosure is not limited thereto, and various embodiments may be applied to the disclosure. PENTILER is a duly registered trademark of Samsung Display Co., Ltd.

According to one or more embodiments, each of the pixels PXL (or each set of sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one of the first sub-pixel SPX1, the second sub-pixel SPX2, and/or the third sub-pixel SPX3 may form a pixel part capable of emitting light of one or more suitable colors.

Each of the first sub-pixels SPX1, the second sub-pixels SPX2, and the third sub-pixels SPX3 may emit light of a color.

For example, the first sub-pixels SPX1 may be red pixels emitting red light (for example, a first color light), the second sub-pixels SPX2 may be green pixels emitting green light (for example, a second color light), and the third sub-pixels SPX3 may be blue pixels emitting blue light (for example, a third color light). The red pixels may provide light in a wavelength range of 600 nm to 750 nm. The green pixels may provide light in a wavelength range of 480 nm to 560 nm. The blue pixels may provide light in a wavelength range of 370 nm to 460 nm.

According to one or more embodiments, the number of second sub-pixels SPX2 may be greater than the number of first sub-pixels SPX1 and the number of third sub-pixels SPX3. However, the color, type, number, and/or the like of the first sub-pixels SPX1, the second sub-pixels SPX2, and the third sub-pixels SPX3 forming each pixel part are/is not limited to a specific example.

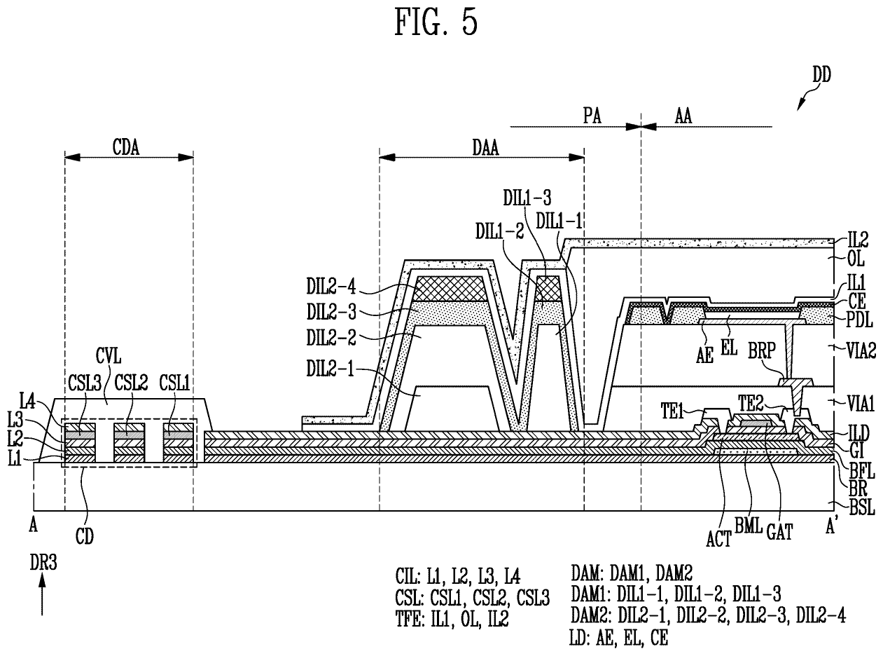

The connection portions COP may be conductive structures formed on the base layer BSL. The connection portions COP may be electrically connected to the sub-pixels SPX through lines. The connection portions COP may be electrically connected to a light emitting element LD (see, e.g., FIG. 5) through lines. The connection portions COP may be electrically connected to a driving circuit part (for example, the gate driver, the data driver, the crack sensing circuit, and/or the like). The connection portions COP may be electrically connected to one end of the chip-on-film COF. In one or more embodiments, another portion of the chip-on-film COF may be arranged on a back surface of the base layer BSL and may be electrically connected to a circuit board or the like arranged on the back surface of the base layer BSL. Accordingly, the chip-on-film COF and the connection portions COP may supply an electrical signal provided from the circuit board or the like to the driving circuit part and the sub-pixels SPX. The circuit board may be configured to control an overall operation of the display device DD.

However, the structure of the display device DD is not necessarily limited thereto. For example, the connection portions COP may be pad portions.

According to one or more embodiments, at least one of the connection portions COP may be electrically connected to the crack sensing line CSL and may be electrically connected to the crack sensing circuit. Accordingly, a sensing signal obtained by the crack sensing line CSL may be applied to the crack sensing circuit.

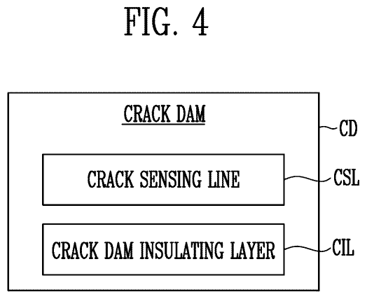

According to one or more embodiments, the display device DD may include a crack dam area CDA. The crack dam area CDA may be an area where a crack dam CD (see, e.g., FIG. 4) is formed.

The crack dam area CDA may be formed at an edge portion of the display device DD. The crack dam area CDA may be arranged in the peripheral area PA. The crack dam area CDA may be arranged at a peripheral portion of the active area AA. The crack dam area CDA may be around (e.g., surround) at least a portion of the active area AA. According to one or more embodiments, the crack dam area CDA may substantially and/or entirely surround the active area AA.

The crack dam area CDA may be arranged on the first side S1 and may also be arranged on the second sides S2. According to one or more embodiments, at least a portion of the crack dam area CDA may be arranged adjacent to the connection portions COP.

The crack sensing line CSL may be formed at an edge portion of the display device DD. The crack sensing line CSL may be arranged in the peripheral area PA. The crack sensing line CSL may be arranged at a peripheral portion of the active area AA. The crack sensing line CSL may be around (e.g., surround) at least a portion of the active area AA. According to one or more embodiments, the crack sensing line CSL may substantially and/or entirely surround the active area AA.

The crack sensing line CSL may obtain a sensing signal regarding a crack that has occurred in the display device DD. For example, when a crack occurs around the crack sensing line CSL, an intensity of an electrical signal obtained by the crack sensing line CSL may change, and thus if (e.g., when) the crack occurs in a part or area of the display device DD, an intensity and/or the like of the crack may be determined, based on the obtained sensing signal. For example, the greater the change the intensity of the electrical signal obtained by the crack sensing line CSL, the greater the likelihood that the crack has a greater intensity.

The display device DD may sense whether the crack occurs in a peripheral area where the crack sensing line CSL is arranged. The crack sensing line CSL may be electrically connected to the crack sensing circuit of the display device DD, and the crack sensing circuit may obtain information on whether a crack occurred in the display device DD, the intensity, and/or the like, based on a crack sensing signal provided from the crack sensing line CSL.

According to one or more embodiments, the crack sensing line CSL may include a plurality of crack sensing lines CSL in the peripheral area PA.

For example (see, e.g., FIG. 1, FIG. 2, and the like), the crack sensing line CSL may include a first crack sensing line CSL1, a second crack sensing line CSL2, and a third crack sensing line CSL3. According to one or more embodiments, the first crack sensing line CSL1, the second crack sensing line CSL2, and the third crack sensing line CSL3 may be sequentially arranged from the active area AA. However, the present disclosure is not limited thereto. In another example (see, e.g., FIG. 3), the crack sensing line CSL may also include a first crack sensing line CSL1 and a second crack sensing line CSL2.

According to one or more embodiments, conductive lines formed by the crack sensing line CSL may be patterned (e.g., formed by patterning), and thus the plurality of crack sensing lines CSL (for example, the first to third crack sensing lines CSL1 to CSL3 or the first and second crack sensing lines CSL1 and CSL2) may be formed.

For example (see, e.g., FIG. 2 and FIG. 3), a conductive line CL formed by the crack sensing line CSL may be formed in a peripheral portion of the active area AA, may be bent at a plurality of positions to provide multiple parallel or substantially parallel conductive lines that are connected to each other and not separate, disconnected lines (e.g., without being disconnected). Accordingly, the plurality of crack sensing lines CSL may form a single continuous conductive line CL in the entire peripheral area PA, and may be formed to be spaced and/or apart (e.g., spaced apart or separated) from each other in the peripheral area PA.

According to one or more embodiments, the conductive line CL formed by the crack sensing line CSL may be electrically connected to the connection portion COP (e.g., at least one of the connection portions CP). For example, a first end EP1 of the conductive line CL may be electrically connected to the connection portion COP, and a second end EP2 of the conductive line CL may be electrically connected to the connection portion COP. Accordingly, the conductive line CL may be electrically connected to the crack sensing circuit electrically connected to the connection portion COP.

According to one or more embodiments, since the crack sensing line CSL is arranged not only on the second sides S2 but also on the first sides S1, information on whether the crack occurs in the display device DD may be thoroughly sensed.

According to one or more embodiments, the crack sensing line CSL may be arranged in the crack dam area CDA. Referring further to FIGS. 4 to 7, the display device DD including the crack sensing line CSL is described in more detail. For convenience of description, a content that may overlap the content described above may be briefly described or may not be repeated.

FIG. 4 is a schematic block diagram illustrating a crack dam according to one or more embodiments of the present disclosure. FIGS. 5 to 7 are each a schematic cross-sectional view illustrating a display device according to one or more embodiments of the present disclosure. FIGS. 5 to 7 each illustrate a schematic cross-sectional view taken along the line A-A′ of FIG. 1, according to one or more embodiments of the present disclosure.

According to one or more embodiments, the crack dam CD may include discontinuous dam portions formed on the base layer BSL. The crack dam CD may reduce a risk that a crack that occurs at an outer portion of the display device DD (for example, an outer portion of the crack dam area CDA) is spread to the of the display device DD inside through various layers. In addition, since the crack dam area CDA is arranged not only on the first side S1, but also on the second sides S2, the risk that the crack spreads to an inside area may be substantially reduced.

The crack dam CD may include a crack dam insulating layer(s) CIL. For example, the crack dam insulating layer CIL may be patterned on the base layer BSL, forming discontinuously protruding structures in the peripheral area PA of the base layer BSL.

According to one or more embodiments, the crack dam insulating layer CIL may be formed as a plurality of layers. For example, the crack dam insulating layer CIL may include first to fourth crack dam insulating layers L1 to L4 (see, e.g., FIG. 5).

According to one or more embodiments, the crack sensing line CSL may be integrated into the structure of the crack dam CD. For example, the crack sensing line CSL may be arranged on a portion of the crack dam insulating layer CIL.

The crack sensing line CSL may form a portion of the crack dam CD (e.g., may be a layer in the crack dam CD). The crack sensing line CSL may form a partial thickness portion (e.g., may form part of the thickness) of the crack dam CD.

The crack sensing line CSL may overlap the crack dam insulating layer CIL in a plan view. For example, the crack sensing line CSL may be arranged on the crack dam insulating layer CIL, and may be arranged under the crack dam insulating layer CIL. In other words, the crack sensing line CSL may be arranged between any of the first to fourth crack dam insulating layers L1 to L4 of the crack dam insulating layer CIL.

According to one or more embodiments, since the crack sensing line CSL is formed in a portion of the crack dam CD, a crack occurring in an outer portion of the display device DD may be thoroughly sensed.

According to one or more embodiments, an area where the crack sensing signal is detected by the crack sensing line CSL and an area where the crack is suppressed from spreading by the crack dam CD may coincide with each other.

Experimentally, when the crack sensing line CSL is separated from the crack dam CD, a portion of crack may spread and reach the crack dam CD, and it may be difficult for the crack sensing line CSL to detect the crack signal early.

However, according to one or more embodiments, since the crack sensing line CSL is arranged in the crack dam area CDA, the crack may be blocked from spreading by the crack dam CD, and information on the occurrence of the crack may be obtained by the crack sensing line CSL. Accordingly, a crack at various positions in the display device DD may be thoroughly sensed, and a risk of a crack spreading in the display device DD may be reduced.

With reference to FIGS. 5 to 7, more detailed cross-sectional structures of the display device DD including the crack sensing line CSL and the crack dam area CDA according to one or more embodiments are described.

First, with reference to FIG. 5, a display device DD according to one or more embodiments will be described in more detail.

In the display device DD according to the embodiments shown in FIG. 5, the crack sensing line CSL may include the first to third crack sensing lines CSL1 to CSL3 as a plurality of lines spaced and/or apart (e.g., spaced apart or separated) from each other.

According to one or more embodiments, the crack sensing lines CSL may be patterned in the same process as at least one conductive layer in the active area AA and may include the same material as at least one conductive layer in the active area AA.

According to one or more embodiments, the crack dam insulating layer CIL may be patterned in the same process as at least one insulating layer arranged in the active area AA and may include the same material as at least one insulating layer arranged in the active area AA.

According to one or more embodiments, the base layer BSL may be arranged across the active area AA and the peripheral area PA. The base layer BSL may be arranged across a dam area DAA and the crack dam area CDA. The dam area DAA may be an area where a dam structure DAM is arranged. According to one or more embodiments, the dam structure DAM may include a first dam structure DAM1 and a second dam structure DAM2. The dam area DAA may also be referred to as an inner dam area.

According to one or more embodiments, the display device DD may include a barrier layer BR and a first crack dam insulating layer L1.

The barrier layer BR may be arranged on the base layer BSL across the active area AA and the peripheral area PA, and may expose a portion of the base layer BSL.

The first crack dam insulating layer L1 may be arranged on the base layer BSL in the peripheral area PA. The first crack dam insulating layer L1 may be arranged in the crack dam area CDA. The first crack dam insulating layer L1 may form a portion of the crack dam CD.

The barrier layer BR and the first crack dam insulating layer L1 may be patterned in the same process and may include the same inorganic material.

According to one or more embodiments, the display device DD may include a lower conductive layer BML.

The lower conductive layer BML may be arranged on the barrier layer BR in the active area AA. In one or more embodiments, a portion of the lower conductive layer BML may be arranged in the peripheral area PA. The lower conductive layer BML may overlap the active layer ACT in a plan view. The lower conductive layer BML may include one or more suitable conductive materials.

According to one or more embodiments, the display device DD may include a buffer layer BFL and a second crack dam insulating layer L2.

The buffer layer BFL may be arranged across the active area AA and the peripheral area PA and may be arranged on the barrier layer BR. The buffer layer BFL may cover the lower conductive layer BML.

The second crack dam insulating layer L2 may be arranged on the first crack dam insulating layer L1 in the peripheral area PA. The second crack dam insulating layer L2 may be arranged in the crack dam area CDA. The second crack dam insulating layer L2 may form a portion of the crack dam CD.

The buffer layer BFL and the second crack dam insulating layer L2 may be patterned in the same process and may include the same inorganic material.

According to one or more embodiments, the display device DD may include an active layer ACT.

The active layer ACT may be arranged on the buffer layer BFL in the active area AA. The active layer ACT may overlap the lower conductive layer BML in a plan view.

The active layer ACT may include one or more suitable semiconductor materials. For example, the active layer ACT may include one or more of polysilicon, low temperature polycrystalline silicon (LTPS), amorphous silicon, and/or an oxide semiconductor. However, the present disclosure is not limited thereto.

According to one or more embodiments, the display device DD may include a gate insulating layer GI and a third crack dam insulating layer L3.

The gate insulating layer GI may be arranged across the active area AA and the peripheral area PA, and may be arranged on the buffer layer BFL. The gate insulating layer GI may cover the active layer ACT.

The third crack dam insulating layer L3 may be arranged on the second crack dam insulating layer L2 in the peripheral area PA. The third crack dam insulating layer L3 may be arranged in the crack dam area CDA. The third crack dam insulating layer L3 may form a portion of the crack dam CD.

The gate insulating layer GI and the third crack dam insulating layer L3 may be patterned in the same process and may include the same inorganic material.

According to one or more embodiments, the display device DD may include a gate conductive layer GAT and the first to third crack sensing lines CSL1 to CSL3.

The gate conductive layer GAT may be arranged on the gate insulating layer GI in the active area AA. The gate conductive layer GAT may overlap the active layer ACT in a plan view. The gate conductive layer GAT may include one or more suitable conductive materials.

The first to third crack sensing lines CSL1 to CSL3 may be spaced and/or apart (e.g., spaced apart or separated) from each other (e.g., in a plan view). The first to third crack sensing lines CSL1 to CSL3 may be arranged on the third crack dam insulating layer L3 in the peripheral area PA. The first to third crack sensing lines CSL1 to CSL3 may be arranged in the crack dam area CDA. According to one or more embodiments, the first to third crack sensing lines CSL1 to CSL3 may form a portion of the crack dam CD.

The gate conductive layer GAT and the first to third crack sensing lines CSL1 to CSL3 may be patterned in the same process and may include the same conductive material.

According to one or more embodiments, the display device DD may include an interlayer insulating layer ILD and a fourth crack dam insulating layer L4.

The interlayer insulating layer ILD may be arranged across the active area AA and the peripheral area PA and may be arranged on the gate insulating layer Gl. The interlayer insulating layer ILD may cover the gate conductive layer GAT.

The fourth crack dam insulating layer L4 may be arranged on the crack sensing line CSL in the peripheral area PA. The fourth crack dam insulating layer L4 may be arranged in the crack dam area CDA. The fourth crack dam insulating layer L4 may form a portion of the crack dam CD.

The interlayer insulating layer ILD and the fourth crack dam insulating layer L4 may be patterned in the same process and may include the same inorganic material.

According to one or more embodiments, the crack dam CD may further include one or more additional insulating layers in addition to the first to fourth crack dam insulating layers L1 to L4 described above.

According to one or more embodiments, the display device DD may include first and second transistor electrodes TE1 and TE2.

The first and second transistor electrodes TE1 and TE2 may be arranged on the interlayer insulating layer ILD in the active area AA, and may be electrically connected to the active layer ACT through a contact member passing through the interlayer insulating layer ILD and the gate insulating layer GI. The first and second transistor electrodes TE1 and TE2 may be a source electrode and a drain electrode, respectively, or may be a drain electrode and a source electrode, respectively. The first and second transistor electrodes TE1 and TE2 may be patterned in the same process and may include the same conductive material.

The first and second transistor electrodes TE1 and TE2, the gate conductive layer GAT, and the active layer ACT may form a pixel circuit for driving the light emitting element LD. For example, the pixel circuit may include a driving transistor, a switching transistor, and/or the like, and may further include a capacitor.

According to one or more embodiments, the display device DD may include a first via layer VIA1, a (2-1)-th dam insulating layer DIL2-1, and a cover layer CVL.

The first via layer VIA1 may be arranged in the active area AA and may be arranged on the interlayer insulating layer ILD. The first via layer VIA1 may cover a portion of the first and second transistor electrodes TE1 and TE2.

The (2-1)-th dam insulating layer DIL2-1 may be arranged in the peripheral area PA (for example, the dam area DAA) and may be arranged on the interlayer insulating layer ILD. The (2-1)-th dam insulating layer DIL2-1 may form a lower portion of the second dam structure DAM2.

The cover layer CVL may be arranged on the base layer BSL in the peripheral area PA. At least a portion of the cover layer CVL may be arranged in the crack dam area CDA. The cover layer CVL may cover the crack dam CD.

The first via layer VIA1, the (2-1)-th dam insulating layer DIL2-1, and the cover layer CVL may be patterned in the same process and may include the same material (for example, an organic material).

According to one or more embodiments, the display device DD may include a bridge layer BRP.

The bridge layer BRP may be arranged on the first via layer VIA1 in the active area AA and may be electrically connected to the second transistor electrode TE2 through a contact member passing through the first via layer VIA1. The bridge layer BRP may include one or more suitable conductive materials.

According to one or more embodiments, the display device DD may include a second via layer VIA2, a (1-1)-th dam insulating layer DIL1-1, and a (2-2)-th dam insulating layer DIL2-2.

The second via layer VIA2 may be arranged in the active area AA and may be arranged on the first via layer VIA1. The second via layer VIA2 may cover a portion of the bridge layer BRP.

The (1-1)-th dam insulating layer DIL1-1 may be arranged in the peripheral area PA (for example, in the dam area DAA). The (1-1)-th dam insulating layer DIL1-1 may form a lower portion of the first dam structure DAM1.

The (2-2)-th dam insulating layer DIL2-2 may be arranged in the peripheral area PA (for example, in the dam area DAA) and may be arranged on the (2-1)-th dam insulating layer DIL2-1. The (2-2)-th dam insulating layer DIL2-2 may form an intermediate lower portion of the second dam structure DAM2.

The second via layer VIA2, the (1-1)-th dam insulating layer DIL1-1, and the (2-2)-th dam insulating layer DIL2-2 may be patterned in the same process and may include the same material (for example, an organic material).

According to one or more embodiments, the display device DD may include an anode electrode AE.

The anode electrode AE may be arranged on the second via layer VIA2 in the active area AA. The anode electrode AE may be electrically connected to the bridge layer BRP through a contact member passing through the second via layer VIA2. The anode electrode AE may include a multilayer structure and may include one or more suitable conductive materials.

According to one or more embodiments, the display device DD may include a pixel defining layer PDL, a (1-2)-th dam insulating layer DIL1-2, and a (2-3)-th dam insulating layer DIL2-3.

The pixel defining layer PDL may be arranged in the active area AA and may cover the anode electrode AE. The pixel defining layer PDL may define an area in which an emission layer EL is electrically connected to the anode electrode AE.

The (1-2)-th dam insulating layer DIL1-2 may be arranged in the peripheral area PA (for example, in the dam area DAA) and may be arranged on the (1-1)-th dam insulating layer DIL1-1. The (1-2)-th dam insulating layer DIL1-2 may form an intermediate portion of the first dam structure DAM1.

The (2-3)-th dam insulating layer DIL2-3 may be arranged in the peripheral area PA (for example, in the dam area DAA) and may be arranged on the (2-2)-th dam insulating layer DIL2-2. The (2-3)-th dam insulating layer DIL2-3 may form an intermediate upper portion of the second dam structure DAM2.

The pixel defining layer PDL, the (1-2)-th dam insulating layer DIL1-2, and the (2-3)-th dam insulating layer DIL2-3 may be patterned in the same process and may include the same material (for example, an inorganic material or an organic material).

According to one or more embodiments, the display device DD may include the emission layer EL.

The emission layer EL may be arranged on the anode electrode AE in the active area AA and may be electrically connected between the anode electrode AE and the cathode electrode CE. According to one or more embodiments, the emission layer EL may emit different colors based on which sub-pixel SPX the emission layer EL corresponds. For example, an emission layer EL included in the first sub-pixel SPX1 may emit light of a first color, an emission layer EL included in the second sub-pixel SPX2 may emit light of a second color, and an emission layer EL included in the third sub-pixel SPX3 may emit light of a third color. However, the present disclosure is not limited thereto.

The emission layer EL may be manufactured using one or more suitable process methods such as a deposition process and/or a coating process. The emission layer EL may include a plurality of layers. For example, the emission layer EL may include a hole transport layer, a light emitting layer (or a light generation layer), and an electron transport layer. Each of the layers forming the emission layer EL may include an organic material, and according to one or more embodiments, may further include an inorganic material such as a metal-containing compound or a quantum dot.

The hole transport layer may include a multilayer structure having a plurality of layers respectively including different materials. For example, the hole transport layer may include a hole injection layer and a hole transport layer, and may further include a light emitting auxiliary layer, an electron blocking layer, and/or the like, according to one or more embodiments.

The light emitting layer may include a material capable of emitting light of a color. The light emitting layer may include a host and a dopant. The host of the light emitting layer may be a light emitting material capable of capturing carriers (an electron and a hole) for generating light, and may induce efficient generation of an exciton. The dopant may include a phosphorescent dopant or a fluorescent dopant. According to one or more embodiments, the dopant is not particularly limited. According to one or more embodiments, the dopant may include an organic material, and/or may also include a metal complex and/or the like.

The electron transport layer may include a multilayer structure having a plurality of layers, each respectively including different materials. The electron transport layer may include an electron injection layer and an electron transport layer, and may further include an electron buffer layer, a hole blocking layer, and/or the like, according to one or more embodiments.

According to one or more embodiments, the display device DD may include a cathode electrode CE.

The cathode electrode CE may be arranged on the pixel defining layer PDL and the emission layer EL in the active area AA. The cathode electrode CE may include one or more suitable conductive materials.

According to one or more embodiments, the anode electrode AE, the emission layer EL, and the cathode electrode CE may form the light emitting element LD.

According to one or more embodiments, the display device DD may include a (1-3)-th dam insulating layer DIL1-3 and a (2-4)-th dam insulating layer DIL2-4.

The (1-3)-th dam insulating layer DIL1-3 may be arranged in the peripheral area PA (for example, in the dam area DAA) and may be arranged on the (1-2)-th dam insulating layer DIL1-2. The (1-3)-th dam insulating layer DIL1-3 may form an upper portion of the first dam structure DAM1.

The (2-4)-th dam insulating layer DIL2-4 may be arranged in the peripheral area PA (for example, in the dam area DAA) and may be arranged on the (2-3)-th dam insulating layer DIL2-3. The (2-4)-th dam insulating layer DIL2-4 may form an upper portion of the second dam structure DAM2.

The (1-3)-th dam insulating layer DIL1-3 and the (2-4)-th dam insulating layer DIL2-4 may be patterned in the same process and may include the same material (for example, an organic material).

The (1-1)-th dam insulating layer DIL1-1, the (1-2)-th dam insulating layer DIL1-2, and the (1-3)-th dam insulating layer DIL1-3 may form the first dam structure DAM1. The first dam structure DAM1 may be an inner dam adjacent to the active area AA and closer to the active area AA than the second dam structure DAM2. The (2-1)-th dam insulating layer DIL2-1, the (2-2)-th dam insulating layer DIL2-2, the (2-3)-th dam insulating layer DIL2-3, and the (2-4)-th dam insulating layer DIL2-4 may form the second dam structure DAM2. The second dam structure DAM2 may be an outer dam further from the active area AA than the first dam structure DAM1.

According to one or more embodiments, the display device DD may include an encapsulation layer TFE. The encapsulation layer TFE may include a first inorganic insulating layer IL1, an organic encapsulation layer OL, and a second inorganic insulating layer IL2.

The first inorganic insulating layer IL1 may be arranged across the active area AA and the peripheral area PA, and may cover the cathode electrode CE, the first dam structure DAM1, the second dam structure DAM2, and the interlayer insulating layer ILD. The first inorganic insulating layer IL1 may include an inorganic material.

The organic encapsulation layer OL may be arranged on the first inorganic insulating layer IL1 in at least a portion of the active area AA and the peripheral area PA. Spread of the organic encapsulation layer OL during a manufacturing process of the display device DD may be prevented by the dam area DAA.

The second inorganic insulating layer IL2 may be arranged across the active area AA and the peripheral area PA and may cover the organic encapsulation layer OL and the first inorganic insulating layer IL1. The second inorganic insulating layer IL2 may include an inorganic material.

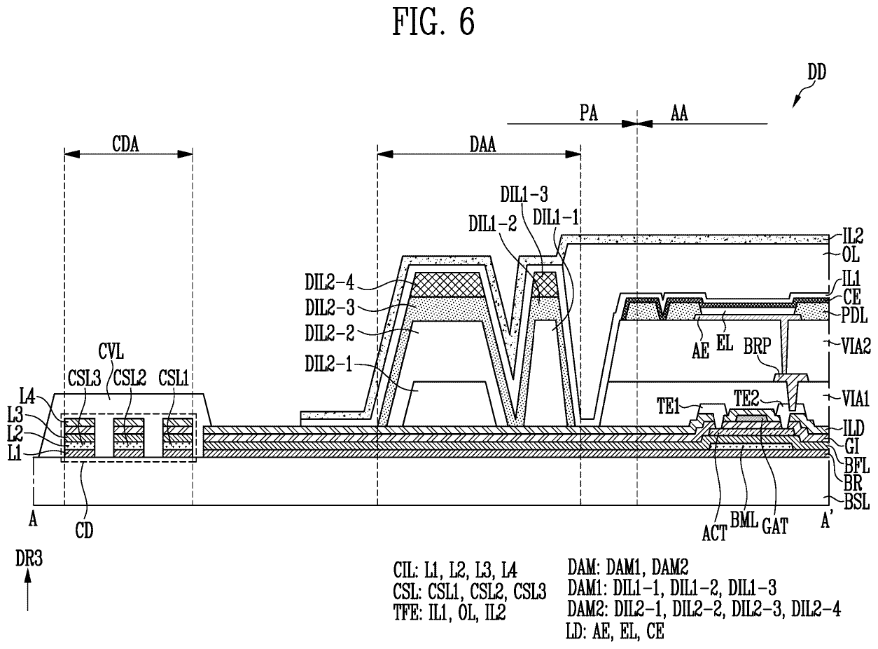

Next, with reference to FIG. 6, a display device DD according to one or more embodiments will be described in more detail.

The display device DD according to the embodiments shown in FIG. 6 is different from the display device DD according to the embodiments shown in FIG. 5, in that the crack sensing lines CSL are patterned in the same process as the lower conductive layer BML.

According to one or more embodiments, the crack sensing lines CSL (for example, the first to third crack sensing lines CSL1 to CSL3) may be formed in the same process and may include the same conductive material as the lower conductive layer BML.

According to one or more embodiments, the second crack dam insulating layer L2 may be patterned in the same process and may include the same material as the buffer layer BFL.

Accordingly, the crack sensing lines CSL may be arranged between the first crack dam insulating layer L1 and the second crack dam insulating layer L2.

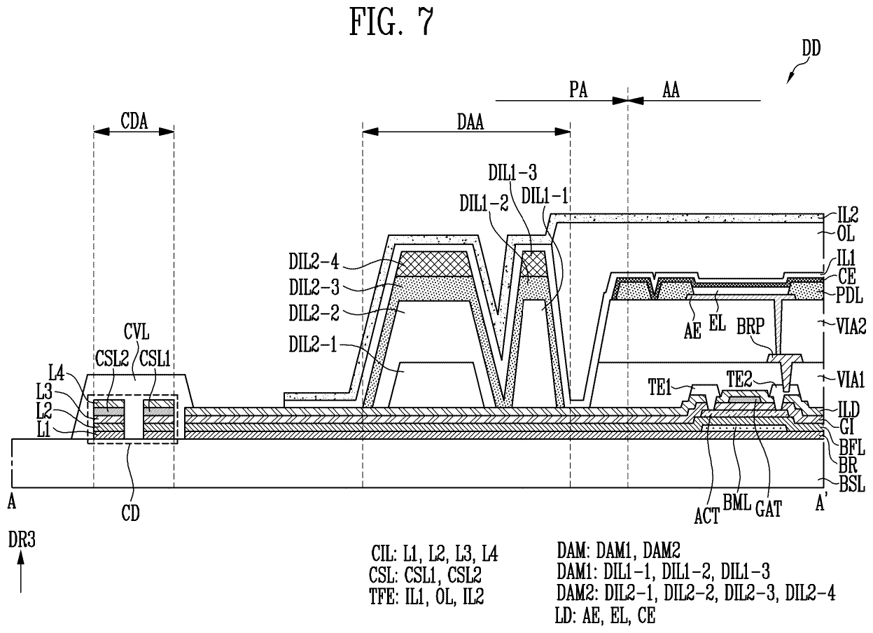

Next, with reference to FIG. 7, a display device DD according to one or more embodiments will be described in more detail.

The display device DD shown in FIG. 7 is different from the display device DD according to the embodiments shown in FIG. 5, in that the number of crack sensing lines CSL is two.

According to one or more embodiments, in the crack dam area CDA, the crack sensing lines CSL may include the first and second crack sensing lines CSL1 and CSL2. In such embodiments, a range (or the size of coverage) of the crack dam area CDA may be reduced, and thus a range (or size) of the peripheral area PA may be relatively reduced.

However, the number of crack sensing lines CSL is not necessarily limited to the above-described example. For example, the number of crack sensing lines CSL may be four or more.

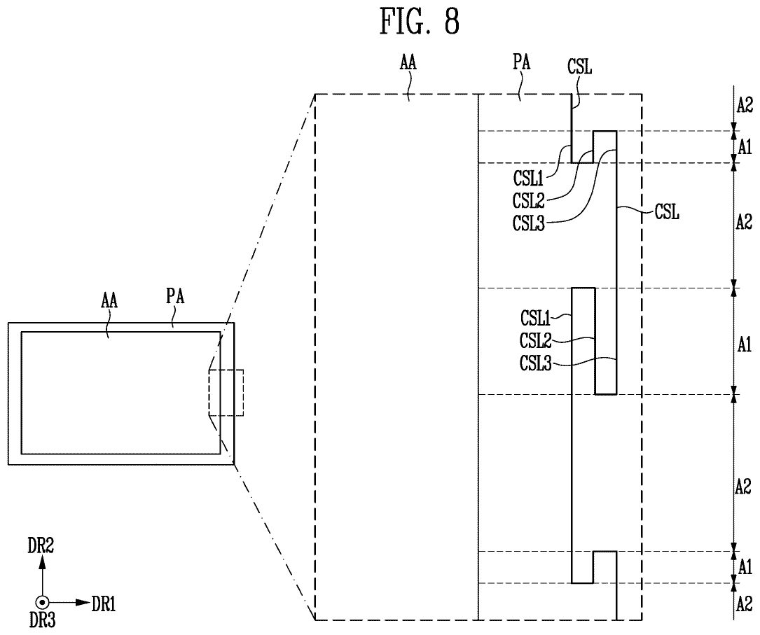

With reference to FIG. 8, a partial overlapping structure of the crack sensing line CSL according to one or more embodiments will be described in more detail.

FIG. 8 is a schematic plan view illustrating a planar structure of the crack sensing line CSL according to one or more embodiments. FIG. 8 illustrates a schematic planar structure of the display device DD including the active area AA and the peripheral area PA, and shows a schematic enlarged view of a partial area including the active area AA and the peripheral area PA.

According to one or more embodiments, the peripheral area PA may include a first area A1 and a second area A2. According to one or more embodiments, the first area A1 and the second area A2 may be spaced and/or apart (e.g., spaced apart or separated) from each other along a direction in which the crack sensing lines CSL generally extend.

The first area A1 may be arranged between adjacent second areas A2, and the second area A2 may be arranged between adjacent first areas A1.

The first area A1 may be an area in which the crack sensing lines CSL are spaced and/or apart (e.g., spaced apart or separated) from each other sequentially along a direction facing an edge inside (of) the display device DD. For example, the first to third crack sensing lines CSL1 to CSL3 spaced and/or apart (e.g., spaced apart or separated) from each other may be arranged in the first area A1. For example, the crack sensing line CSL may form a plurality of lines in the first area A1.

The second area A2 may be an area in which a single crack sensing line CSL is arranged along a direction facing an edge inside the display device DD. For example, the crack sensing line CSL may form a single line in the second area A2.

According to one or more embodiments, the crack sensing line CSL may be folded one or more times between the first area A1 and the second area A2. FIG. 8 shows embodiments in which the crack sensing line CSL is folded twice between the first area A1 and the second area A2, and thus the first to third crack sensing lines CSL1 to CSL3 are formed in the first area A1.

According to one or more embodiments, the crack sensing line CSL in the second area A2 may be integral with one of the crack sensing lines CSL in the first area A1 at a one side of the second area A2 and may be integral with one of the crack sensing lines CSL in the first area A1 at another side of the second area A2. For example, the crack sensing line CSL in the second area A2 may be continuously integral with the third crack sensing line CSL3 in the first area A1 at one side of the second area A2, and may be continuously integral with the third crack sensing line CSL3 in the first area A1 at another side of the second area A2. According to one or more embodiments, the crack sensing line CSL in the second area A2 may be continuously connected to one of the crack sensing lines CSL in the first area A1 at a side of the second area A2, and may be continuously connected to one of the crack sensing lines CSL in the first area A1 at another side of the second area A2.

According to one or more embodiments, the first area A1 may be a position where a risk of crack occurrence in the display device DD is high, and the second area A2 may be a position where the risk of crack occurrence in the display device DD is relatively low. Thus, according to one or more embodiments, the number of crack sensing lines CSL may be adjusted according to the risk of crack occurrence.

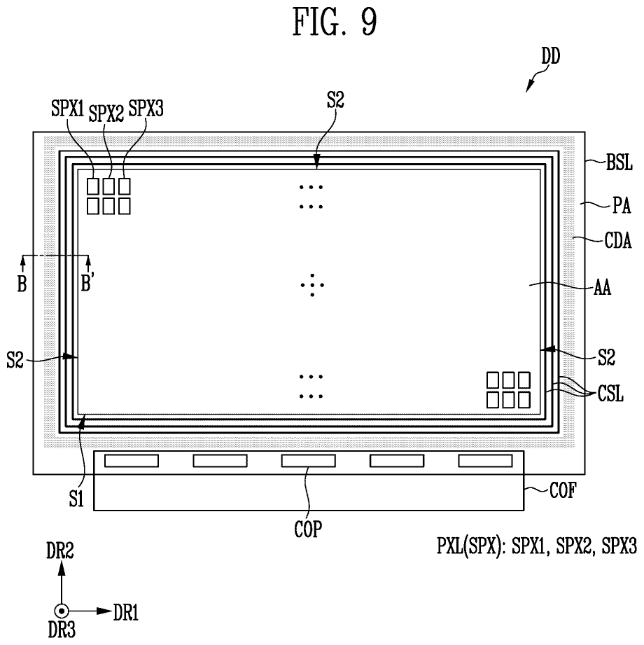

With reference to FIGS. 9 to 13, a display device DD according to one or more embodiments will be described in more detail. For convenience of description, a content that may overlap the content described above may be briefly described or may not be repeated.

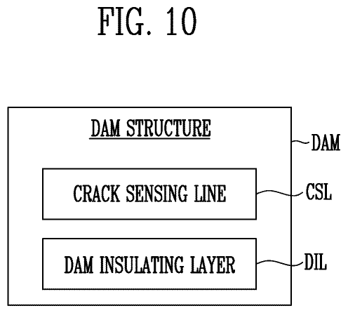

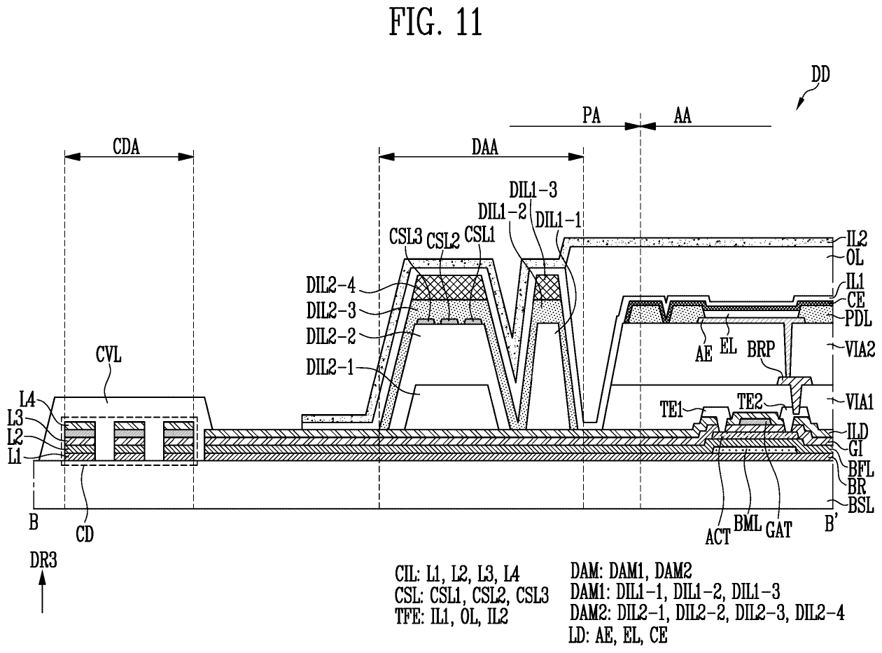

FIG. 9 is a schematic plan view illustrating a display device according to one or more embodiments of the present disclosure. FIG. 10 is a schematic block diagram illustrating a crack dam according to one or more embodiments of the present disclosure. FIGS. 11 to 13 are each a schematic cross-sectional view illustrating a display device according to one or more embodiments of the present disclosure. FIGS. 11 to 13 each show a schematic cross-sectional view taken along the line B-B′ of FIG. 9, according to one or more embodiments of the present disclosure.

Referring to FIGS. 9 to 13, the display device DD according to the present embodiments are different from the display device DD according to the embodiments described above with reference to FIGS. 1 to 8, in that the crack sensing line CSL is provided in the dam area DAA.

According to one or more embodiments, the crack sensing line CSL may not be arranged in the crack dam area CDA. The crack sensing line CSL may be more adjacent to the active area AA than the crack dam area CDA.

The dam structure DAM may include a dam insulating layer DIL. For example, as the dam insulating layer DIL is patterned on the base layer BSL, protruding dam structures DAM may be formed in the peripheral area PA of the base layer BSL.

According to one or more embodiments, the dam insulating layer DIL may be formed by a plurality of layers. For example, as described above with reference to FIGS. 5 to 7, the dam insulating layer DIL may include the (1-1)-th dam insulating layer DIL1-1, the (1-2)-th dam insulating layer DIL1-2, and the (1-3)-th dam insulating layer DIL1-3 forming the first dam structure DAM1, and may include the (2-1)-th dam insulating layer DIL2-1, the (2-2)-th dam insulating layer DIL2-2, the (2-3)-th dam insulating layer DIL2-3, and the (2-4)-th dam insulating layer DIL2-4 forming the second dam structure DAM2.

According to one or more embodiments, the crack sensing line CSL may be integrated into the dam structure DAM. For example, the crack sensing line CSL may be arranged on a portion of the dam insulating layer DIL.

The crack sensing line CSL may form a portion of the dam structure DAM. The crack sensing line CSL may form a partial thickness portion (e.g., may form part of the thickness) of the dam structure DAM.

The crack sensing line CSL may overlap the dam insulating layer DIL in a plan view. For example, the crack sensing line CSL may be arranged on the dam insulating layer DIL, and/or may be arranged under the dam insulating layer DIL.

According to one or more embodiments, since the crack sensing line CSL is arranged in the dam area DAA, crack sensing for an area in the display device DD where an effect of the crack may be relatively large may be thoroughly performed and/or available.

For example, when the display device DD is a bendable or foldable electronic device, a possibility that stress may be generated inside the display device DD may exist. In such embodiments, a possibility that the crack may occur in the dam structure DAM having a protruding shape may be relatively high.

According to one or more embodiments, since the crack sensing line CSL may be arranged in the dam area DAA, a crack risk occurring in the dam structure DAM may be thoroughly monitored, and the crack risk may be reduced.

Referring to FIGS. 11 to 13, a cross-sectional structure regarding one or more embodiments in which the crack sensing line CSL is arranged in the dam area DAA is provided.

Referring to FIG. 11, the crack sensing lines CSL may be formed in the second dam structure DAM2 and may not be formed in the first dam structure DAM1.

For example, the crack sensing lines CSL may include the first to third crack sensing lines CSL1 to CSL3. According to one or more embodiments, the first to third crack sensing lines CSL1 to CSL3 may overlap the second dam structure DAM2 arranged in an outer portion of the dam area DAA relative to the first dam structure DAM1. For example, the first to third crack sensing lines CSL1 to CSL3 may be arranged on the (2-2)-th dam insulating layer DIL2-2 and may be covered by the (2-3)-th dam insulating layer DIL2-3.

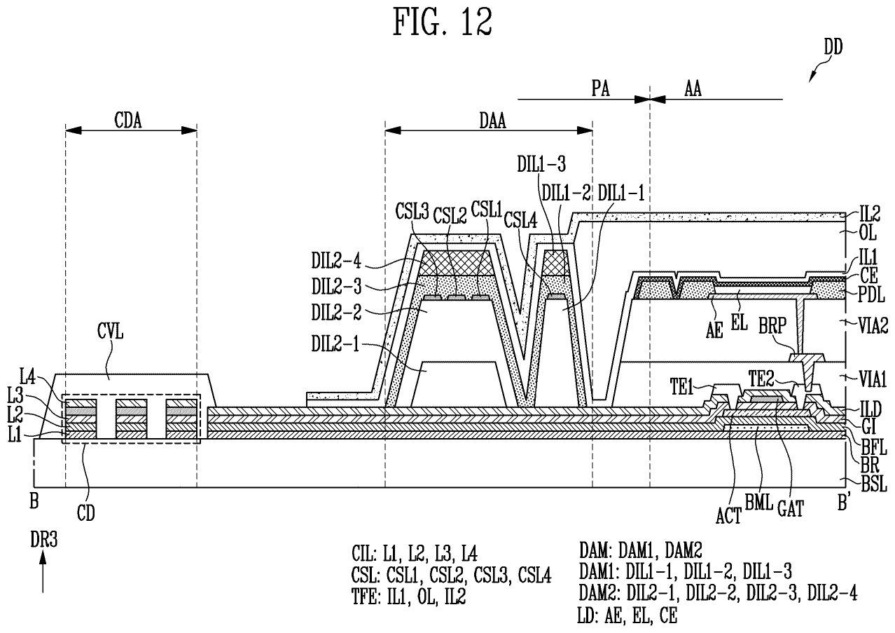

Referring to FIG. 12, the crack sensing lines CSL may be formed in the first dam structure DAM1 and may also be formed in the second dam structure DAM2.

For example, the crack sensing lines CSL may include first to fourth crack sensing lines CSL1 to CSL4. According to one or more embodiments, the first to third crack sensing lines CSL1 to CSL3 may overlap the second dam structure DAM2, which is positioned in an outer portion of the dam area DAA relative to the first dam structure DAM1. The fourth crack sensing line CSL4 may overlap the first dam structure DAM1. For example, the first to third crack sensing lines CSL1 to CSL3 may be arranged on the (2-2)-th dam insulating layer DIL2-2 and may be covered by the (2-3)-th dam insulating layer DIL2-3. The fourth crack sensing line CSL4 may be arranged on the (1-1)-th dam insulating layer DIL1-1 and may be covered by the (1-2)-th dam insulating layer DIL1-2.

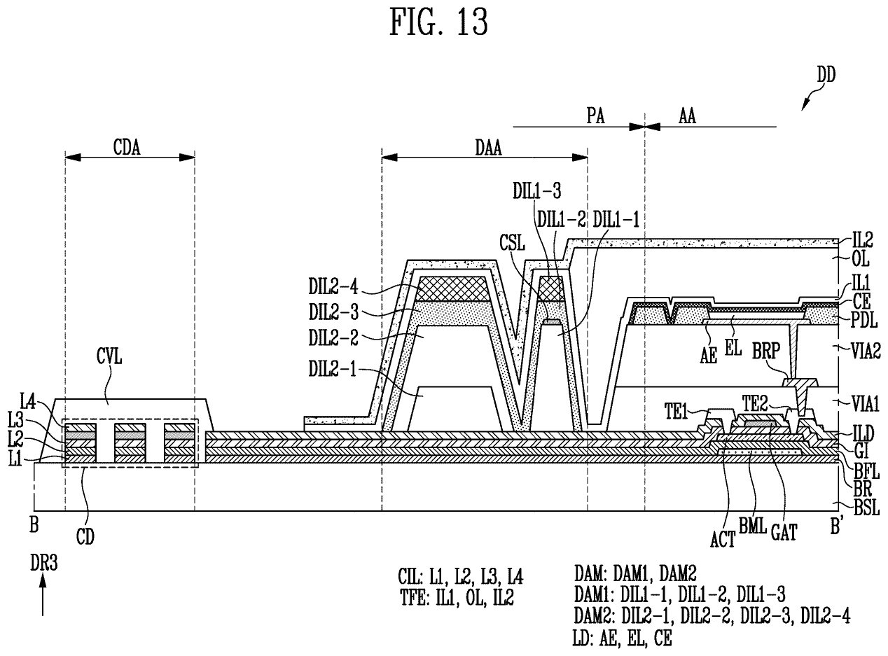

Referring to FIG. 13, the crack sensing lines CSL may be formed in the first dam structure DAM1 and may not be formed in the second dam structure DAM2.

For example, the crack sensing line CSL may overlap the first dam structure DAM1. For example, the crack sensing line CSL may be arranged on the (1-1)-th dam insulating layer DIL1-1 and may be covered by the (1-2)-th dam insulating layer DIL1-2. According to one or more embodiments, the crack sensing lines CSL may be formed only in the first dam structure DAM1, and a plurality of crack sensing lines CSL may be formed.

Hereinafter, an electronic device 1000 including the display device DD in accordance with an embodiment will be described.

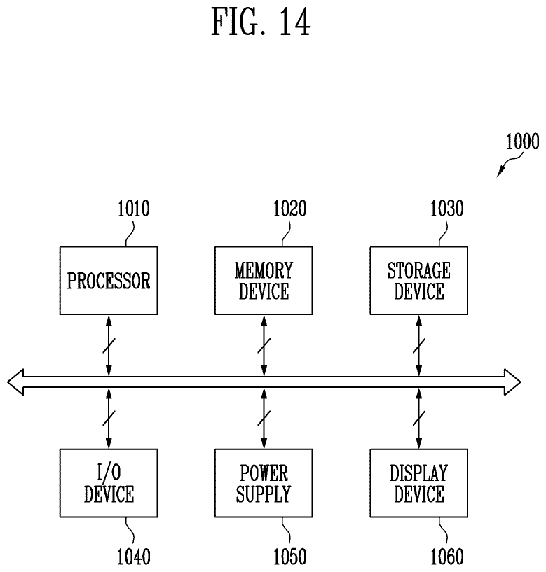

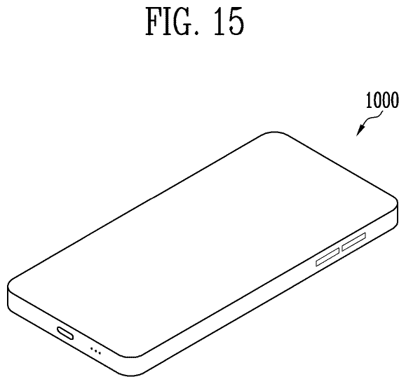

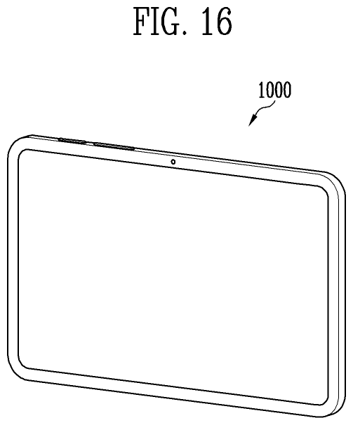

FIG. 14 is a schematic block diagram illustrating an electronic device 1000 including a display device in accordance with an embodiment. FIG. 15 is a schematic diagram illustrating an example where the electronic device 1000 of FIG. 14 is implemented as a smartphone. FIG. 16 is a schematic diagram illustrating an example where the electronic device 1000 of FIG. 14 is implemented as a tablet computer.

Referring to FIGS. 14 to 16, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, or other systems. In an embodiment, as illustrated in FIG. 15, the electronic device 1000 may be implemented as a smartphone. In an embodiment, as illustrated in FIG. 16, the electronic device 1000 may be implemented as a tablet computer. However, the aforementioned examples are illustrative, and the electronic device 1000 is not necessarily limited to the aforementioned examples. For example, the electronic device 1000 may be implemented as a cellular phone, a video phone, a smartpad, a smartwatch, a navigation device for vehicles, a computer monitor, a laptop computer, a head-mounted display device, or the like.

The processor 1010 may perform specific calculations or tasks. In an embodiment, the processor 1010 may be a micro-processor, a central processing unit, an application processor, or the like. The processor 1010 may be connected to other components through an address bus, a control bus, a data bus, and the like. In an embodiment, the processor 1010 may be connected to an expansion bus such as a peripheral component interconnect (PCI) bus. In an embodiment, the processor 1010 may provide input image data to the display device 1060. Hence, the display device 1060 may display an image based on the input image data provided from the processor 1010.

The memory device 1020 may store data needed to perform the operation of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, or the like.

The I/O device 1040 may include input devices such as a keyboard, a keypad, a touchpad, a touch screen, and a mouse, and output devices such as a speaker and a printer. In an embodiment, the display device 1060 may be included in the I/O device 1040.

The power supply 1050 may supply power needed to perform the operation of the electronic device 1000. For example, the power supply 1050 may be a power management integrated circuit (PMIC). In an embodiment, the power supply 1050 may supply power to the display device 1060.

The display device 1060 may display an image corresponding to visual information of the electronic device 1000. The display device 1060 may be connected to other components through the buses or other communication links.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a base layer having an active area and a peripheral area, the peripheral area around at least a portion of the active area and having a crack dam area;
a light emitting element on the base layer in the active area;
a crack dam on the base layer in the crack dam area, and including a crack dam insulating layer; and
a crack sensing line in the crack dam area.

2. The display device as claimed in claim 1, wherein the crack sensing line comprises a plurality of crack sensing lines spaced from each other in a direction from the active area to an outer portion of the display device.

3. The display device as claimed in claim 2, further comprising:
connection portions electrically connected to the light emitting element; and
a chip-on-film electrically connected to the connection portions,
wherein the active area comprises a first side and second sides that are sides other than the first side,
the connection portions are on the first side and are not on the second sides, and
the crack sensing line is on the first side and the second sides.

4. The display device as claimed in claim 3, wherein the crack sensing line is electrically connected to at least one of the connection portions.

5. The display device as claimed in claim 3, wherein the crack dam is on the first side and the second sides.

6. The display device as claimed in claim 1, wherein the crack sensing line is integral with the crack dam and on the crack dam insulating layer.

7. The display device as claimed in claim 1, further comprising at least one conductive layer in the active area and at least one insulating layer in the active area,
wherein the crack sensing line comprises the same material as the at least one conductive layer, and
the crack dam insulating layer comprises the same material as the at least one insulating layer.

8. The display device as claimed in claim 1, further comprising:
a lower conductive layer on the base layer in the active area;
an active layer overlapping the lower conductive layer in the active area;
a gate conductive layer overlapping the active layer in the active area; and
a transistor electrode layer electrically connected to the active layer,
wherein the crack sensing line comprises the same material as the gate conductive layer.

9. The display device as claimed in claim 1, further comprising:
a lower conductive layer on the base layer in the active area;
an active layer overlapping the lower conductive layer in the active area;
a gate conductive layer overlapping the active layer in the active area; and
a transistor electrode layer electrically connected to the active layer,
wherein the crack sensing line comprises the same material as the lower conductive layer.

10. The display device as claimed in claim 7, wherein the crack sensing line comprises a first crack sensing line, a second crack sensing line, and a third crack sensing line spaced from each other.

11. The display device as claimed in claim 10, wherein the crack sensing line comprises a conductive line in the peripheral area, and
the conductive line is bent at a plurality of positions to form the first crack sensing line, the second crack sensing line, and the third crack sensing line without being disconnected.

12. The display device as claimed in claim 11, wherein the peripheral area comprises a first area and a second area, and
the crack sensing line comprises a plurality of lines in the first area and comprises a single line in the second area.

13. The display device as claimed in claim 12, wherein the single line in the second area is continuously connected to one of the plurality of lines in the first area.

14. A display device comprising:
a base layer having an active area, a peripheral area, the peripheral area around at least a portion of the active area and having a dam area;
a crack dam on the base layer in the peripheral area, and comprising a crack dam insulating layer;
a dam structure between the crack dam and the active area, in the dam area, and including a dam insulating layer; and
a crack sensing line in the dam area.

15. The display device as claimed in claim 14, wherein the crack sensing line is integral with the dam structure.

16. The display device as claimed in claim 15, wherein the crack sensing line is on the dam insulating layer.

17. The display device as claimed in claim 14, wherein the dam structure comprises a first dam structure and a second dam structure spaced from each other, and
the crack sensing line is in the first dam structure and is not in the second dam structure.

18. The display device as claimed in claim 14, wherein the dam structure comprises a first dam structure and a second dam structure spaced from each other, and
the crack sensing line is in each of the first dam structure and the second dam structure.

19. The display device as claimed in claim 14, wherein the dam structure comprises a first dam structure and a second dam structure spaced from each other, and
the crack sensing line is in the second dam structure and is not in the first dam structure.

20. A display device comprising:
a base layer having an active area and a peripheral area, the peripheral area around at least a portion of the active area;
a light emitting element on the base layer in the active area;
a connection portion on the base layer in the peripheral area, at a side of the peripheral area, and electrically connected to the light emitting element;
a chip-on-film having at least a portion electrically connected to the connection portion;
a crack dam on the base layer in the peripheral area and comprising a crack dam insulating layer; and
a crack sensing line in the peripheral area and comprising a plurality of crack sensing lines.

21. An electronic device, comprising:
a processor configured to provide input image data;
a display device configured to display an image based on the input image data, the display device including sub-pixel areas; and
a power supply configured to supply power to the display device,
wherein the display device comprises: a base layer having an active area and a peripheral area, the peripheral area around at least a portion of the active area and having a crack dam area; a light emitting element on the base layer in the active area; a crack dam on the base layer in the crack dam area, and including a crack dam insulating layer; and a crack sensing line in the crack dam area.
